(19) United States
(12) Patent Application Publication
(10) Pub. No.: US 2009/0227058 A1
(43) Pub. Date: Sep. 10, 2009

(54) PHOTORESIST COMPOSITION AND METHOD OF MANUFACTURING ARRAY SUBSTRATE USING THE SAME

(75) Inventors: Jeong-Min PARK, Seoul (KR); Doo-Hee JUNG, Seoul (KR); Hi-Kuk LEE, Yongin-si (KR); Byung-Uk KIM, Hwaseong-si (KR); Dong-Min KIM, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si, Gyeonggi-do (KR)

(21) Appl. No.: 12/347,202

(22) Filed: Dec. 31, 2008

(30) Foreign Application Priority Data
Mar. 4, 2008 (KR) 2008-20109

(51) Int. Cl. H01L 21/027; G03F 7/004

(52) U.S. Cl. 438/34; 430/270.1; 257/E21.026

(57) ABSTRACT

A photoresist composition includes; a novolac resin prepared from a phenol compound, wherein the m-cresol constitutes about 70% to about 85% by weight of the weight of the phenol compound, a diazide compound, and an organic solvent.

This application claims priority to Korean Patent Application No. 2008-20109, filed on Mar. 4, 2008, and all the benefits accruing therefrom under 35 U.S.C. §119, the contents of which in its entirety are herein incorporated by reference.

### BACKGROUND OF THE INVENTION

1. Field of the Invention

The present invention relates to a photoresist composition and a method of manufacturing an array substrate using the photoresist composition. More particularly, the present invention relates to a photoresist composition for manufacturing a liquid crystal display (“LCD”) apparatus and a method of manufacturing an array substrate using the photoresist composition.

2. Description of the Related Art

Generally, a liquid crystal display (“LCD”) panel includes an array substrate having switching devices for driving a pixel area, an opposing substrate facing the array substrate and a liquid crystal layer interposed between the array substrate and the opposing substrate. The LCD panel applies a voltage to the liquid crystal layer to control light transmittance of individual pixels of the display, thereby displaying an image.

The array substrate is manufactured through a photolithography process using a photoresist composition. The array substrate is manufactured through a four-mask process using four masks for simplifying manufacturing processes; as opposed to a five-, or more, mask process. According to the four-mask process, a photoresist pattern having different thicknesses is formed using a mask having a slit portion or a halftone portion. A remaining pattern having different thicknesses is formed from the photoresist pattern. Accordingly, the remaining pattern having varying thickness is formed from the photoresist pattern so that different patterns are formed from two layers through a process using a mask instead of a conventional process using two masks. A photoresist composition used for the processes needs to have a high developing contrast based on a developing speed difference between an exposed portion and an unexposed portion. The residual uniformity of a half-exposed portion corresponding to the slit portion or the halftone portion is also important. Furthermore, the photoresist composition needs to have high adhesion in order to improve selectivity so that a lower layer under the photoresist pattern may not be etched and so that a lower layer in a region where the photoresist pattern does not exist may be etched.

In view of manufacturing efficiency, a photoresist composition having improved sensitivity is necessary for improving the efficiency of conventional devices for manufacturing a photoresist pattern, such as an exposing device, e.g., a mask.

However, when the sensitivity of the photoresist composition is improved, the residual uniformity of the half-exposed portion may be reduced, thereby reducing the reliability of manufacturing processes. Thus, a photoresist composition for manufacturing an LCD apparatus, which is capable of improving the above-mentioned characteristics, without deteriorating other characteristics, is desired.

### BRIEF SUMMARY OF THE INVENTION

The present invention provides a photoresist composition capable of improving a sensitivity and the residual uniformity of a half-exposed portion of a photoresist pattern.

The present invention also provides a method of manufacturing an array substrate using the above-mentioned photoresist composition.

In one exemplary embodiment of the present invention, a photoresist composition includes; a novolac resin prepared from a phenol compound, wherein m-cresol constitutes about 70% to about 85% of the weight of the phenol compound, a diazide compound and an organic solvent.

In one exemplary embodiment, the novolac resin may include; a first novolac resin prepared from a phenol compound, wherein the phenol compound includes m-cresol and p-cresol in a ratio of about 40:60 to about 60:40 by weight, and a second novolac resin prepared from a phenol compound, wherein the phenol compound includes m-cresol and p-cresol in a ratio of about 90:10 to about 100:0 by weight.

In one exemplary embodiment, the diazide compound may include a diazide compound combined with a phenol compound. In one exemplary embodiment, the weight average molecular weight of the phenol compound combined with the diazide compound maybe about 500 to 1,500 g/mol.

In another exemplary embodiment of the present invention, there is provided an exemplary embodiment of a method of manufacturing an array substrate, the method including; disposing a source metal layer on a base substrate having a gate line and a gate electrode connected to the gate line, disposing a photoresist pattern on the source metal layer, the photoresist pattern being formed from a photoresist composition including; a novolac resin prepared from a phenol compound, wherein m-cresol constitutes about 70% to about 85% of the weight of the phenol compound, a diazide compound, and an organic solvent, forming a data line substantially perpendicular to the gate line, a source electrode connected to the data line and a drain electrode spaced apart from the source electrode from the source metal layer using the photoresist pattern, and electrically connecting a pixel electrode to the drain electrode.

According to the above, a photoresist composition according to an exemplary embodiment of the present invention may improve a sensitivity, a developing contrast between an exposed portion and an unexposed portion, and the residual uniformity of a half-exposed portion. Furthermore, the exemplary embodiment of a photoresist composition may increase adhesion to a substrate thereby increasing reliability of a metal pattern. Therefore, the reliability and efficiency of manufacturing processes may be increased.

### BRIEF DESCRIPTION OF THE DRAWINGS

The above and other advantages of the present invention will become readily apparent by reference to the following detailed description when considered in conjunction with the accompanying drawings wherein:

FIG. 1 is a top plan layout view illustrating an exemplary embodiment of an array substrate manufactured according to an exemplary embodiment of the present invention; and

FIGS. 2-7 are cross-sectional views illustrating an exemplary embodiment of a method of manufacturing an exemplary embodiment of an array substrate according to the present invention.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on,”” another element, it can be directly on the other element or intervening elements may be present therebetween. In contrast, when an element is referred to as being “directly on,” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Exemplary embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

<Photoresist Composition>

A photoresist composition according to an exemplary embodiment of the present invention includes a) a novolac resin, b) a diazide compound and c) an organic solvent as will be discussed in detail below.

<a) Novolac Resin>

An exemplary embodiment of the novolac resin used in the present invention may be prepared by reacting a phenol compound with an aldehyde compound or a ketone compound in the presence of an acidic catalyst.

Exemplary embodiments of the phenol compound may include phenol, o-cresol, m-cresol, p-cresol, 2,3-dimethylphenol, 3,4-dimethylphenol, 3,5-dimethylphenol, 2,4-dimethylphenol, 2,6-dimethylphenol, 2,3,6-trimethylphenol, 2-t-butylphenol, 3-t-butylphenol, 4-t-butylphenol, 2-methylresorcinol, 4-methylresorcinol, 5-methylresorcinol, 4-t-butylcatechol, 2-methoxyphenol, 3-methoxyphenol, 2-propylphenol, 3-propylphenol, 4-propylphenol, 2-isopropylphenol, 2-methoxy-5-methylphenol, 2-t-butyl-5-methylphenol, thymol, isothymol, or other materials having similar characteristics. Exemplary embodiments include configurations wherein the phenol compounds may be used alone or in combination.

Exemplary embodiments of the aldehyde compound may include formaldehyde, formalin, p-formaldehyde, trioxane, acetaldehyde, benzaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-chlorobenzaldehyde, m-chlorobenzaldehyde, p-chlorobenzaldehyde, o-methylbenzaldehyde, m-methylbenzaldehyde, p-methylbenzaldehyde, p-ethylbenzaldehyde, p-n-butylbenzaldehyde, terephthalic acid aldehyde, or other materials having similar characteristics. Exemplary embodiments include configurations wherein the phenol compounds maybe used alone or in combination.

Exemplary embodiments of the ketone compound may include acetone, methylethylketone, diethylketone, diphenylketone, or other materials having similar characteristics. Exemplary embodiments include configurations wherein the phenol compounds may be used alone or in combination.

In one exemplary embodiment, the novolac resin may be prepared from a phenol compound including about 70% to about 85% by weight of m-cresol. When the content of m-cresol is less than about 70% by weight, a reactivity difference of a photoresist film with respect to light is increased even if the light is uniformly provided to the photoresist film. Thus, the thickness of a photoresist pattern formed through a developing process may not be uniform. Furthermore, the residual uniformity of a half-exposed portion may be reduced. When the thickness of the photoresist pattern is not uniform, the reliability of a lower metal pattern formed by using the photoresist pattern as an etching mask may be reduced.

In the exemplary embodiment wherein the content of m-cresol is less than about 85% by weight, the content of other components, for example, p-cresol, is relatively reduced. Thus, controlling the sensitivity of a photoresist composition may be difficult. Thus, in one exemplary embodiment, the content of m-cresol of the phenol compound used for preparing the novolac resin may be about 70% to about 85% by weight based on the total weight of the phenol compound.

In one exemplary embodiment, the novolac resin of the photoresist composition may include a first novolac resin and a second novolac resin, which are different from each other. In such an exemplary embodiment, the first novolac resin or the second novolac resin may be prepared from a phenol compound having an m-cresol content of less than about 70% by weight or greater than about 85% by weight such that the average content of m-cresol included in the first and second phenol compounds, which are respectively used for preparing the first and second novolac resins, is about 70% to about 85% by weight based on the total weight of the phenol compound including the first and second phenol compounds. In one exemplary embodiment, the first phenol compound may include m-cresol and p-cresol in a ratio of about 40:60 to about 60:40 by weight, and the second phenol compound may include m-cresol and p-cresol in a ratio of about 80:20 to about 100:0 by weight. In one exemplary embodiment, a ratio of the first novolac resin and the second novolac resin may be about 10:90 to about 60:40 by weight.

As described above, in one exemplary embodiment, the novolac resin of the photoresist composition may include a first novolac resin and a second novolac resin. The first novolac resin may be prepared from a first phenol compound including m-cresol and p-cresol in a ratio of about 40:60 by weight, and the second novolac resin may be prepared from a second phenol compound including only m-cresol. In such an exemplary embodiment, a ratio of the first novolac resin and the second novolac resin may be about 40:60 by weight, and the average content of m-cresol may be about 76% by weight based on the total weight of the first and second phenol compounds.

In an alternative exemplary embodiment, the novolac resin may include a first novolac resin prepared from a first phenol compound including m-cresol and p-cresol in a ratio of about 50:50 by weight and a second novolac resin prepared from a first phenol compound including m-cresol and p-cresol in a ratio of about 90:10 by weight. In such an exemplary embodiment, a ratio of the first novolac resin and the second novolac resin may be about 40:60 to about 50:50 by weight, and the average content of m-cresol may be about 70% to about 74% by weight based on the total weight of the phenol compound including the first and second phenol compounds.

In an alternative exemplary embodiment, the novolac resin may include a first novolac resin prepared from a first phenol compound including m-cresol and p-cresol in a ratio of about 60:40 by weight and a second novolac resin prepared from a first phenol compound including m-cresol and p-cresol in a ratio of about 80:20 by weight. In such an exemplary embodiment, a ratio of the first novolac resin and the second novolac resin may be about 40:60 to about 50:50 by weight, and the average content of m-cresol may be about 70% to about 72% by weight based on the total weight of the phenol compound including the first and second phenol compounds.

In an exemplary embodiment, the novolac resin may include a first novolac resin prepared from a first phenol compound including m-cresol and p-cresol in a ratio of about 60:40 by weight and a second novolac resin prepared from a first phenol compound including only m-cresol. In such an exemplary embodiment, a ratio of the first novolac resin and the second novolac resin may be about 40:60 to about 60:40 by weight, and the average content of m-cresol may be about 76% to about 84% by weight based on the total weight of the phenol compound including the first and second phenol compounds.

In one exemplary embodiment, a ratio of a first novolac resin and a second novolac resin may be about 10:90 to about 60:40 by weight when the novolac resin includes a first novolac resin and a second novolac resin, which are different from each other. A particular ratio of the first and second novolac resin may be selected such that the average content of m-cresol may be about 70% to about 85% by weight based on the total weight of the phenol compound including the first and second phenol compounds.

When the weight average molecular weight of the novolac resin is less than about 4,000 g/mol, a dissolving speed of the novolac resin in a developing solution is increased. Thus, controlling the sensitivity of a photoresist composition may be difficult, and a solubility difference between an exposed portion and an unexposed portion may be reduced. Therefore, a fine photoresist pattern may be difficult to form. When the weight average molecular weight of the novolac resin is greater than about 15,000 g/mol, a dissolving speed of the novolac resin in a developing solution may be reduced. Thus, forming a photoresist pattern at a desired sensitivity may be difficult. Therefore, in one exemplary embodiment, the weight average molecular weight of the novolac resin may be about 4,000 to about 15,000 g/mol. In one exemplary embodiment, the weight average molecular weight is represented by a polystyrene-reduced weight average molecular weight measured by gel permeation chromatography (“GPC”).

When the content of the novolac resin is less than about 5% by weight based on the total weight of the photoresist composition, the viscosity of the photoresist composition may be excessively reduced. Thus, forming a photoresist film having a desired thickness may be difficult. When the content of the novolac resin is greater than about 30% by weight the viscosity of the photoresist composition may be excessively increased. Thus, coating the photoresist composition on a substrate may be difficult. Thus, in one exemplary embodiment, the content of the novolac resin may be about 5% to about 30% by weight based on the total weight of the photoresist composition.

<b) Diazide Compound>

The diazide compound may serve as a photosensitizer controlling a photosensitizing speed. Exemplary embodiments of the diazide compound may include 1,2-naphthoquinonediazide-5-sulfonate, 2,3,4-trihydroxybenzophenone-1,2-naphthoquinonediazide-5-sulfonate, 2,3,4,4′-tetrahydroxybenzophenone-1,2-naphthoquinonediazide-5-sulfonate, or other materials having similar characteristics. Exemplary embodiments include configurations wherein the diazide compound may be used alone or in combination. In one exemplary embodiment, the diazide compound may include 2,3,4-trihydroxybenzophenone-1,2-naphthoquinonediazide-5-sulfonate.

In on exemplary embodiment, the diazide compound may further include an adhesion enhancement agent increasing adhesion between a substrate and the novolac resin. Exemplary embodiments of the adhesion enhancement agent may include a diazide compound combined with a phenol compound as a ballast. In such an exemplary embodiment, the phenol compound combined with the diazide compound may serve as a ballast so that the diazide compound is stabilized. The adhesion enhancement agent may increase the attractive force between a substrate and the novolac resin, and may uniformly disperse the novolac resin in the organic solvent of the photoresist composition, to thereby increase adhesion between a photoresist pattern and a substrate. In one exemplary embodiment, the phenol compound may include 1,2-naphthoquinonediazide-5-sulfonate combined with a phenol compound represented by the following Chemical Formula 1 as a ballast.

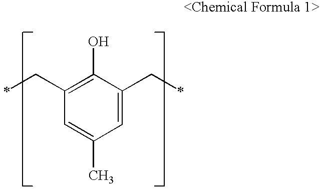

When the weight average molecular weight of the phenol compound combined with the diazide compound is less than about 500, the adhesion enhancement agent may not sufficiently increase the attractive force between a substrate and the novolac resin. When the weight average molecular weight of the phenol compound combined with the diazide compound is greater than about 1,500 g/mol, the size of the phenol compound may be excessively increased so that the attractive force between a substrate and the novolac resin is reduced. Thus, in one exemplary embodiment, the weight average molecular weight of the phenol compound combined with the diazide compound may be about 500 to about 1,500 gmol.

When the weight ratio of the diazide compound as a photosensitizer and the adhesion enhancement agent is less than about 40:60, for example, about 30:70, the sensitivity of the photoresist composition may be reduced, and the adhesion of the photoresist composition with respect to a substrate may be reduced. Thus, a lower metal layer covered by a photoresist pattern formed from the photoresist composition may be more likely to become corroded. When the weight ratio of the diazide compound as a photosensitizer and the adhesion enhancement agent is greater than about 60:40, for example, about 80:20, stripping the photoresist composition from a substrate may be difficult. Thus, in one exemplary embodiment, the weight ratio of the diazide compound as a photosensitizer and the adhesion enhancement agent may be about 40:60 to about 60:40.

When the content of the diazide compound including a photosensitizer and an adhesion enhancement agent is less than about 2% by weight based on the total weight of the photoresist composition, the sensitivity of the photoresist composition may be excessively reduced, and adhesion between a photoresist film and a substrate may be reduced. When the content of the diazide compound including a photosensitizer and an adhesion enhancement agent is greater than about 10%, the sensitivity of the photoresist composition may be excessively increased so that controlling a sensitizing speed may be difficult. Thus, in one exemplary embodiment, the content of the diazide compound including a photosensitizer and an adhesion enhancement agent may be about 2% to about 10% by weight based on the total weight of the photoresist composition.

<c) Organic Solvent>

Exemplary embodiments of the solvent include alcohols, exemplary embodiments of which include methanol and ethanol, ethers, exemplary embodiments of which include tetrahydrofurane, glycol ethers such as ethylene glycol monomethyl ether and ethylene glycol monoethyl ether, ethylene glycol alkyl ether acetates such as methyl cellosolve acetate and ethyl cellosolve acetate, diethylene glycols such as diethylene glycol monomethyl ether, diethylene glycol monoethyl ether and diethylene glycol dimethyl ether, propylene glycol monoalkyl ethers such as propylene glycol methyl ether, propylene glycol ethyl ether, propylene glycol propyl ether and propylene glycol butyl ether, propylene glycol alkyl ether acetates such as propylene glycol methyl ether acetate, propylene glycol ethyl ether acetate, propylene glycol propyl ether acetate and propylene glycol butyl ether acetate, propylene glycol alkyl ether propionates such as propylene glycol methyl ether propionate, propylene glycol ethyl ether propionate, propylene glycol propyl ether propionate and propylene glycol butyl ether propionate, aromatic compounds such as toluene and xylene, ketones such as methyl ethyl ketone, cyclohexanone and 4-hydroxy-4-methyl-2-pentanone, and ester compounds such as methyl acetate, ethyl acetate, propyl acetate, butyl acetate, ethyl 2-hydroxypropionate, methyl 2-hydroxy-2-methyl propionate, ethyl 2-hydroxy-2-methyl propionate, methyl hydroxyacetate, ethyl hydroxyacetate, butyl hydroxyacetate, methyl lactate, ethyl lactate, propyl lactate sulfate, butyl lactate, methyl 3-hydroxypropionate, ethyl 3-hydroxypropionate, propyl 3-hydroxypropionate, butyl 3-hydroxypropionate, methyl 2-hydroxy-3-methyl butanoate, methyl methoxy acetate, ethyl methoxy acetate, propyl methoxy acetate, butyl methoxy acetate, methyl ethoxy acetate, ethyl ethoxy acetate, propyl ethoxy acetate, butyl ethoxy acetate, methyl propoxy acetate, ethyl propoxy acetate, propyl propoxy acetate, butyl propoxy acetate, methyl butoxy acetate, ethyl butoxy acetate, propyl butoxy acetate, butyl butoxy acetate, methyl 2-methoxypropionate, ethyl 2-methoxypropionate, propyl 2-methoxypropionate, butyl 2-methoxypropionate, methyl 2-ethoxypropionate, ethyl 2-ethoxypropionate, propyl 2-ethoxypropionate, butyl 2-ethoxypropionate, methyl 2-butoxypropionate, ethyl 2-butoxypropionate, propyl 2-butoxypropionate, butyl 2-butoxypropionate, methyl 3-methoxypropionate, ethyl 3-methoxypropionate, propyl 3-methoxypropionate, butyl 3-methoxypropionate, methyl 3-ethoxypropionate, ethyl 3-ethoxypropionate, propyl 3-ethoxypropionate, butyl 3-ethoxypropionate, methyl 3-propoxypropionate, ethyl 3-propoxypropionate, propyl 3-propoxypropionate, butyl 3-propoxypropionate, methyl 3-butoxypropionate, ethyl 3-butoxypropionate, propyl 3-butoxypropionate, butyl 3-butoxypropionate, or other materials having similar characteristics.

In one exemplary embodiment, glycol ethers, ethylene glycol alkyl ether acetates and diethylene glycols are used in view of the solubility and reactivity of each of the components composing the photoresist composition and a manufacturing condition of a coating layer. In one exemplary embodiment, propylene glycol methyl ether acetate may be used.

<d) Additive>

An exemplary embodiment of a photoresist composition according to the present invention may further include an additive such as a coloring agent, a dye, a scratch inhibitor, a plasticizer, a surfactant, or other additives as would be known to one of ordinary skill in the art in order to adjust or improve characteristics of the photoresist composition to be suitable for manufacturing processes.

Hereinafter, an exemplary embodiment of a photoresist composition according to the present invention will be described more fully with reference to Examples and Comparative Examples.

### EXAMPLE 1

About 12 g of a first novolac resin having a weight average molecular weight of about 5,000 and about 8 g of a second novolac resin having a weight average molecular weight of about 6,000; about 4 g of a diazide compound including about 2 g of 2,3,4-trihydroxybenzophenone-1,2-naphthoquinonediazide-5-sulfonate and about 2 g of 1,2-naphthoquinonediazide-5-sulfonate combined with a phenol compound represented by the following Chemical Formula 1 as a ballast; and about 60 g of propylene glycol methyl ether acetate were mixed uniformly to prepare a first exemplary embodiment of a photoresist composition. The first novolac resin was prepared from a phenol compound including m-cresol and p-cresol in a weight ratio of about 60:40, and the second novolac resin was prepared from a phenol compound including m-cresol and p-cresol in a weight ratio of about 90:10. The viscosity of the photoresist composition was about 15 cP.

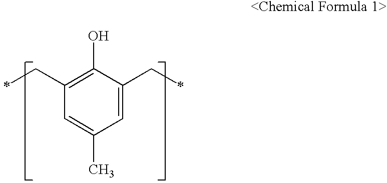

### EXAMPLE 2

About 10 g of a first novolac resin having a weight average molecular weight of about 6,000 g/mol and about 10 g of a second novolac resin having a weight average molecular weight of about 6,000 g/mol; about 4 g of a diazide compound including about 2 g of 2,3,4-trihydroxybenzophenone-1,2-naphthoquinonediazide-5-sulfonate and about 2 g of 1,2-naphthoquinonediazide-5-sulfonate combined with a phenol compound represented by the Chemical Formula 1 as a ballast; and about 60 g of propylene glycol methyl ether acetate were mixed uniformly to prepare a second exemplary embodiment of a photoresist composition. The first novolac resin was prepared from a phenol compound including m-cresol and p-cresol in a weight ratio of about 50:50, and the second novolac resin was prepared from a phenol compound including m-cresol and p-cresol in a weight ratio of about 90:10. The viscosity of the photoresist composition was about 15 cP.

### EXAMPLE 3

About 12 g of a first novolac resin having a weight average molecular weight of about 8,000 gmol and about 8 g of a second novolac resin having a weight average molecular weight of about 6,000 g/mol; about 4 g of a diazide compound including about 2 g of 2,3,4-trihydroxybenzophenone-1,2-naphthoquinonediazide-5-sulfonate and about 2 g of 1,2-naphthoquinonediazide-5-sulfonate combined with a phenol compound represented by the Chemical Formula 1 as a ballast; and about 60 g of propylene glycol methyl ether acetate were mixed substantially uniformly to prepare a third exemplary embodiment of a photoresist composition. The first novolac resin was prepared from a phenol compound including m-cresol and p-cresol in a weight ratio of about 60:40, and the second novolac resin was prepared from a phenol compound including m-cresol and p-cresol in a weight ratio of about 90:10. The viscosity of the photoresist composition was about 15 cP.

### EXAMPLE 4

About 10 g of a first novolac resin having a weight average molecular weight of about 8,000 g/mol and about 10 g of a second novolac resin having a weight average molecular weight of about 6,000 g/mol; about 4 g of a diazide compound including about 2 g of 2,3,4-trihydroxybenzophenone-1,2-naphthoquinonediazide-5-sulfonate and about 2 g of 1,2-naphthoquinonediazide-5-sulfonate combined with a phenol compound represented by the Chemical Formula 1 as a ballast; and about 60 g of propylene glycol methyl ether acetate were mixed uniformly to prepare a fourth exemplary embodiment of a photoresist composition. The first novolac resin was prepared from a phenol compound including m-cresol and p-cresol in a weight ratio of about 60:40, and the second novolac resin was prepared from a phenol compound including m-cresol and p-cresol in a weight ratio of about 90:10. The viscosity of the photoresist composition was about 15 cP.

### COMPARATIVE EXAMPLE 1

About 20 g of a novolac resin having a weight average molecular weight of about 5,000; about 4 g of a diazide compound including about 2 g of 2,3,4-trihydroxybenzophenone-1 2-naphthoquinonediazide-5-sulfonate and 2 g of 2,3,4,4′-tetrahydroxybenzophenone-1,2-naphthoquinonediazide-5-sulfonate; and about 60 g of propylene glycol methyl ether acetate were mixed uniformly to prepare a photoresist composition according to a first comparative embodiment. The novolac resin was prepared from a phenol compound including m-cresol and p-cresol in a weight ratio of about 60:40. The viscosity of the photoresist composition was about 15 cP.

### COMPARATIVE EXAMPLE 2

About 12 g of a first novolac resin having a weight average molecular weight of about 5,000 and about 8 g of a second novolac resin having a weight average molecular weight of about 6,000 g/mol; about 4 g of a diazide compound including about 2 g of 2,3,4-trihydroxybenzophenone-1,2-naphthoquinonediazide-5-sulfonate and 2 g of 2,3,4,4′-tetrahydroxybenzophenone-1,2-naphthoquinonediazide-5-sulfonate; and about 60 g of propylene glycol methyl ether acetate were mixed uniformly to prepare a photoresist composition according to a second comparative embodiment. The first novolac resin was prepared from a phenol compound including m-cresol and p-cresol in a weight ratio of about 60:40, and the second novolac resin was prepared from a phenol compound including m-cresol and p-cresol in a weight ratio of about 90:10. The viscosity of the photoresist composition was about 15 cP.

<Evaluation of Photoresist Composition>

Each of the exemplary embodiments of photoresist compositions of Examples 1 to 4 and the comparative photoresist compositions of Comparative Examples 1 to 2 was dropped on a glass substrate having a thickness of about 0.7 mm, then spin-coated at a predetermined speed, and then dried under a pressure of about 0. 1 torr for about 60 seconds while reducing the pressure. Thereafter, the glass substrate was heated at a temperature of about 110° C. for about 90 seconds to dry the photoresist composition so as to form a photoresist film having a thickness of about 1.90 μm. The photoresist film was exposed to ultraviolet (“UV”) light having a wavelength of about 365 nm to about 435 nm, and then developed by an aqueous solution including tetramethylammonium oxide for about 60 seconds to form a photoresist pattern. A sensitivity and a residual ratio of the photoresist pattern was measured, and the results obtained thereby are illustrated in the following Table 1. Thereafter, the photoresist pattern was hard-baked at a temperature of about 130° C.

In order to evaluate the adhesion of the photoresist pattern, a metal layer including molybdenum (Mo) was formed on a glass substrate, and a photoresist pattern was formed on the metal layer according to substantially the same method as the above-mentioned photoresist pattern. An etching solution was provided on the photoresist pattern. Thereafter, a thickness of an unexposed portion, e.g., a portion of the metal layer disposed under the photoresist pattern, was measured, and thus obtained results are illustrated in the following Table 1.

TABLE 1

| | | | | | Comparative | Comparative |
|---|---|---|---|---|---|---|
| | Example 1 | Example 2 | Example 3 | Example 4 | Example 1 | Example 2 |
| Sensitivity | 30 | 24 | 40 | 32 | 50 | 32 |
| (mJ/cm²) | | | | | | |
| Residual | 93 | 92 | 95 | 94 | 94 | 94 |
| ratio (%) | | | | | | |
| Halftone | 0.60 | 0.57 | 0.65 | 0.60 | 0.72 | 0.61 |
| gradient | | | | | | |
| Adhesion | 0.8 | 0.9 | 0.7 | 0.6 | 1.25 | 1.15 |
| (μm) | | | | | | |

In Table 1, the sensitivity represents an energy level required for fully dissolving the photoresist film in the developing solution, and the residual ratio represents a value calculated by the following equations:

Initial thickness of photoresist film=reduced thickness through etching+remaining thickness after etching (Equation: 1)

Residual ratio=(remaining thickness/initial thickness) (Equation: 2)

When the photoresist film was fully removed by the etching solution, a light amount of a fully-exposed portion was considered to be 100, and a light amount of a half-exposed portion was considered to be 50. Light amounts of about 30%, about 40%, about 50% and about 60% of the light amount of the half-exposed portion were respectively irradiated onto the photoresist film. Thereafter, the photoresist film was developed, and a thickness of a remaining film was measured. A graph was plotted such that an x-coordinate represented the light amount and a y-coordinate represented the thickness of the remaining film. The halftone gradient represents a gradient value of the graph.

Referring to Table 1, it can be noted that halftone gradients of the photoresist compositions of Examples 1 to 4 are less than those of the photoresist compositions of Comparative Examples 1 and 2 (with the exception of the exemplary embodiment of Example 3 and the comparative embodiment of Comparative Example 2). As the halftone gradient was reduced, a thickness difference varied depending on the light amount of the half-exposed portion may be reduced. Thus, the residual uniformity of the half-exposed portion formed from the exemplary embodiments of photoresist compositions of Examples 1 to 4 is greater than that of the half-exposed portion formed from the photoresist compositions of Comparative Examples 1 and 2.

Furthermore, the adhesion represents an etched thickness of an unexposed portion under the photoresist pattern in Table 1. Thus, the adhesion of the photoresist pattern formed from the exemplary embodiments of photoresist compositions of Examples 1 to 4 is greater than that of the photoresist pattern formed from the photoresist compositions of Comparative Examples 1 and 2.

Comparing the photoresist compositions of Comparative Examples 1 and 2, it can be noted that the exemplary embodiments of photoresist compositions of Examples 1 to 4 may improve the residual uniformity of a half-exposed portion and adhesion of the photoresist pattern, while maintaining a sensitivity level and residual ratio comparable to the photoresist compositions of Comparative Examples 1 and 2.

Hereinafter an exemplary embodiment of a method of manufacturing an array substrate according to the present invention will be described more fully with reference accompanying drawings.

<Method of Manufacturing a Thin-Film Transistor (“TFT”) Substrate>

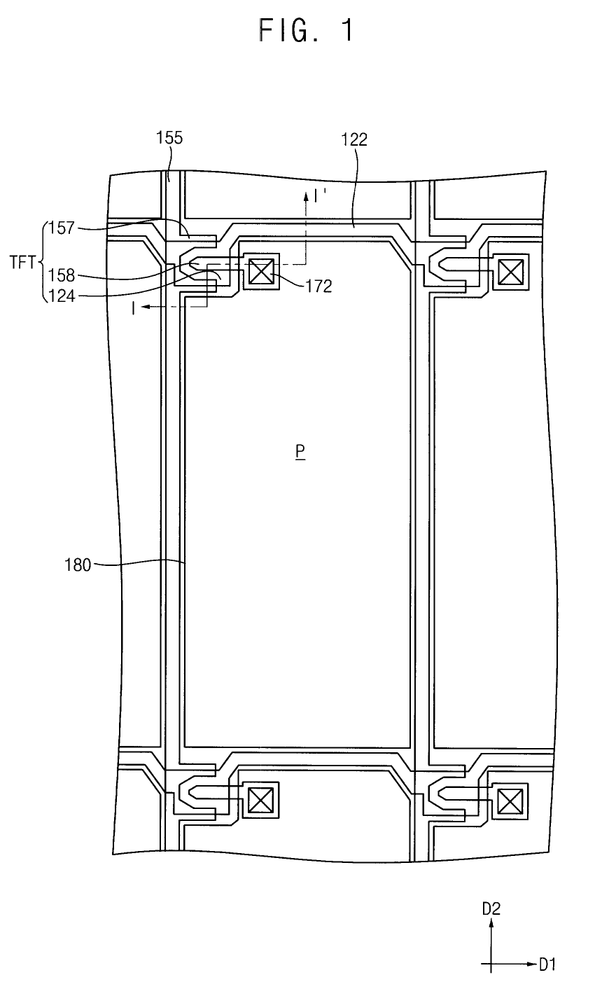

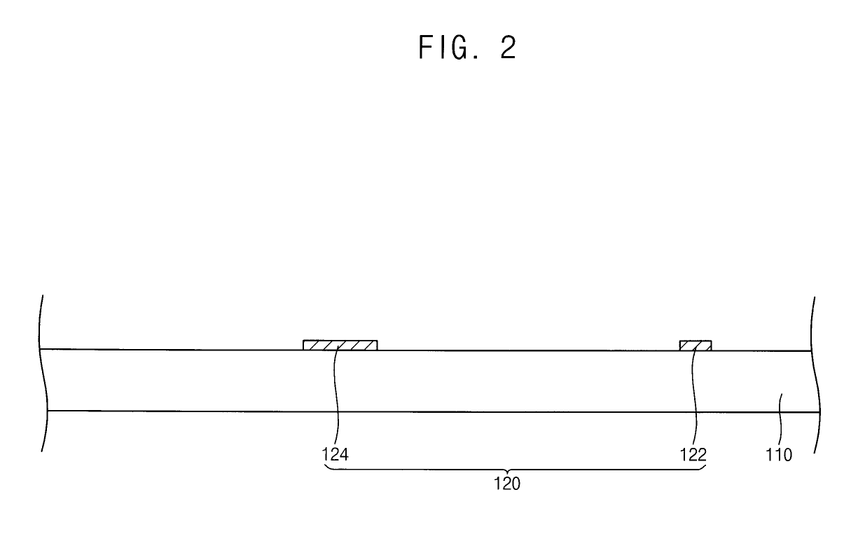

FIG. 1 is a top plan view illustrating an exemplary embodiment of an array substrate manufactured according to an exemplary embodiment of the present invention. FIGS. 2-7 are cross-sectional views illustrating an exemplary embodiment of a method of manufacturing an exemplary embodiment of an array substrate according to the present invention. Particularly, FIGS. 2-7 respectively illustrate cross-sectional views taken along line I-I′ of FIG. 1.

Referring to FIGS. 1 and 2, after a gate metal layer is formed on a base substrate 110, the gate metal layer is patterned through a photolithography process using a first mask to form a gate pattern 120. The gate pattern 120 includes a gate line 122 and a gate electrode 124 electrically connected to the gate line 122. The gate line 122 extends in a first direction D1, and a plurality of gate electrodes 124 may be arranged to extend from the gate line 122 in a second direction D2 different from the first direction D1. In one exemplary embodiment, the first direction D1 may be substantially perpendicular to the second direction D2. The gate electrode 124 is connected to the gate line 122, and serves as a gate terminal of a thin-film transistor (“TFT”) formed in a pixel P.

In one exemplary embodiment, the base substrate 110 may be a transparent insulation substrate. In one exemplary embodiment, the base substrate 110 may include glass, or other materials with similar characteristics.

In one exemplary embodiment, the gate metal layer may be formed on the base substrate 110 through a sputtering method. The gate metal layer may be etched through a wet-etching process. In one exemplary embodiment, the gate pattern 120 may include aluminum (Al), molybdenum (Mo), neodymium (Nd), chromium (Cr), tantalum (Ta), titanium (Ti), tungsten (W), copper (Cu), silver (Ag), alloys thereof, and other materials with similar characteristics. In one exemplary embodiment, the gate pattern 120 may have a double-layer structure including at least two metal layers having different physical characteristics. In one exemplary embodiment, the gate pattern 120 may have an aluminum/molybdenum (Al/Mo) double-layer structure including an aluminum (Al) layer and a molybdenum (Mo) layer so as to reduce resistance.

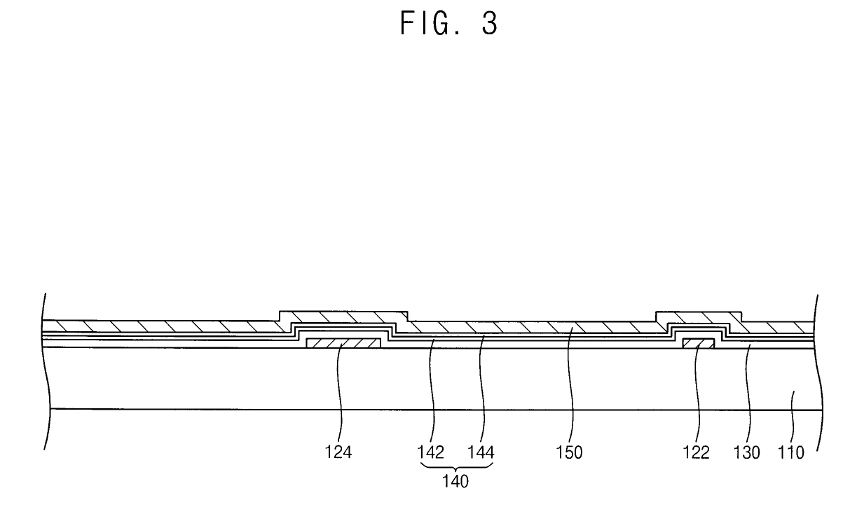

FIGS. 3-7 are cross-sectional views illustrating processes of forming a source pattern and a channel portion. Referring to FIG. 3, a gate insulation layer 130 and an active layer 140 are sequentially formed on the base substrate 110 having the gate pattern 120. The gate insulation layer 130 and the active layer 140 may be formed through a plasma-enhanced chemical vapor deposition (“PECVD”) method.

The gate insulation layer 130 may protect and insulate the gate pattern 120. In one exemplary embodiment, the gate insulation layer 130 may include silicon nitride, silicon oxide, and other materials with similar characteristics. In one exemplary embodiment, a thickness of the gate insulation layer 130 maybe about 4,500 Å.

In the present exemplary embodiment, the active layer 140 includes a semiconductor layer 142 and an ohmic contact layer 144. In one exemplary embodiment, the semiconductor layer 142 may include amorphous silicon (a-Si), and examples of a material that may be used for the ohmic contact layer 133 may include a-Si into which n⁺ impurities are implanted at a high concentration.

A source metal layer 150 is formed on the active layer 140. In one exemplary embodiment, the source metal layer 150 may have a molybdenum/aluminum/molybdenum (Mo/Al/Mo) triple-layer structure so as to reduce the resistance of the source metal layer 150. In an alternative exemplary embodiment, the source metal layer 150 may have a single layer including molybdenum (Mo), aluminum (Al), alloys thereof, or other materials having similar characteristics.

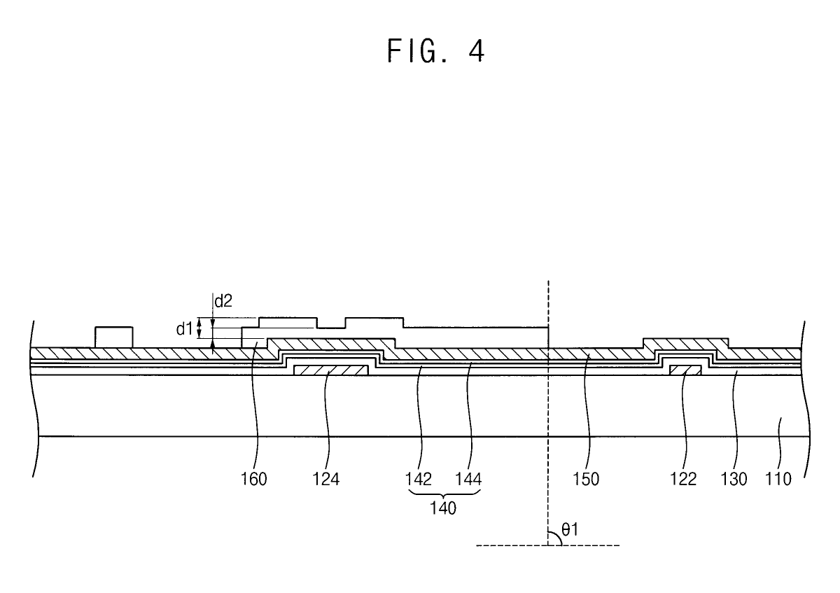

Referring to FIG. 4, a photoresist composition is coated on the source metal layer 150 to form a photoresist film. The photoresist film is exposed to light by a second mask, exemplary embodiments of which include a slit mask or a halftone mask, and then developed to form a first photoresist pattern 160.

According to the present exemplary embodiment, the photoresist composition includes a) a novolac resin prepared from a phenol compound including about 70% to about 85% by weight of m-cresol; b) a diazide compound; and c) an organic solvent. The photoresist composition is substantially the same as the photoresist composition previously described above. Thus, any further description will be omitted.

The first photoresist pattern 160 includes a first portion having a first thickness d1 and a second portion having a second thickness d2. The first portion is formed on a source electrode/line portion and a drain electrode portion. The second portion is formed on a channel portion. The second thickness d2 is less than the first thickness d1. In the present exemplary embodiment, the second portion is half-exposed to light through a slit portion or a half-transmitting portion of the second mask.

According to an exemplary embodiment of the present invention, the photoresist film may be uniformly coated on the base substrate 110, and the second portion, e.g., the half-exposed portion of the photoresist pattern, may increase residual uniformity. Furthermore, the photoresist film may have an improved developing contrast between an exposed portion and an unexposed portion and may have improved adhesion to a lower metal layer. Thus, an angle formed between a sidewall of the photoresist pattern 160 and an upper surface of the base substrate 110 may be increased. In one exemplary embodiment, the angle θ1 formed between a sidewall of the photoresist pattern 160 and an upper surface of the base substrate 110 may be about 80° to about 90°.

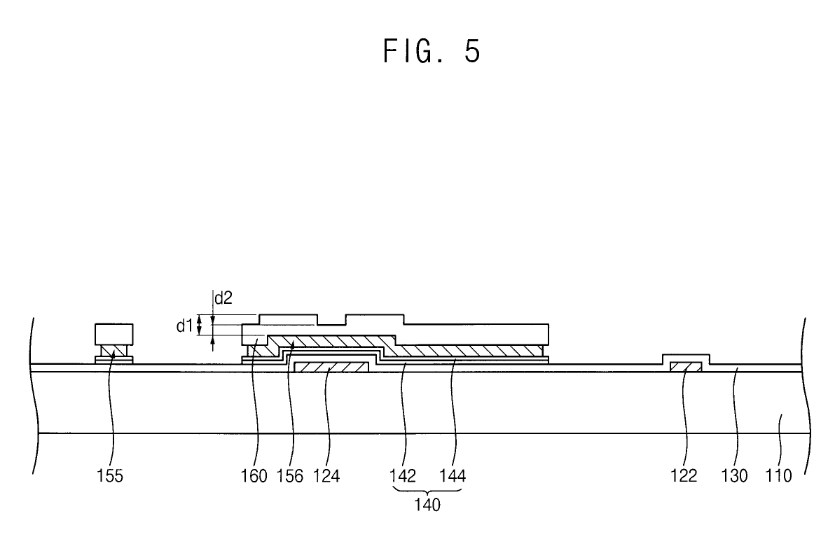

Referring to FIGS. 1 and 5, the source metal layer 150 is etched using the first photoresist pattern 160 as an etching mask to form a data line 155 and a switching pattern 156. In one exemplary embodiment, the source metal layer 150 may be etched through a wet etching process. The data line 155 may be disposed substantially perpendicular to the gate line 122, and the switching pattern 156 is connected to the data line 155. In the present exemplary embodiment, the data line 155 extends in the second direction D2, and a plurality of data lines 155 are arranged in the first direction.

Thereafter, the active layer 140 is etched by using the first photoresist pattern 160, the data line 155 and the switching pattern 156 as an etching mask. In the present exemplary embodiment, the active layer 150 may be etched through a dry etching process. Since the angle θ1 formed between a sidewall of the photoresist pattern 160 and an upper surface of the base substrate 110 is relatively close to 90°, e.g., the sidewall of the photoresist pattern 160 is substantially perpendicular to the base substrate 110, an etched side surface of the active layer 140 may substantially coincide with etched side surfaces of the data line 155 and the switching pattern 156. Therefore, a protrusion of the active pattern 140, which laterally protrudes from the data line 155 and the switching pattern 156, may be reduced or effectively prevented.

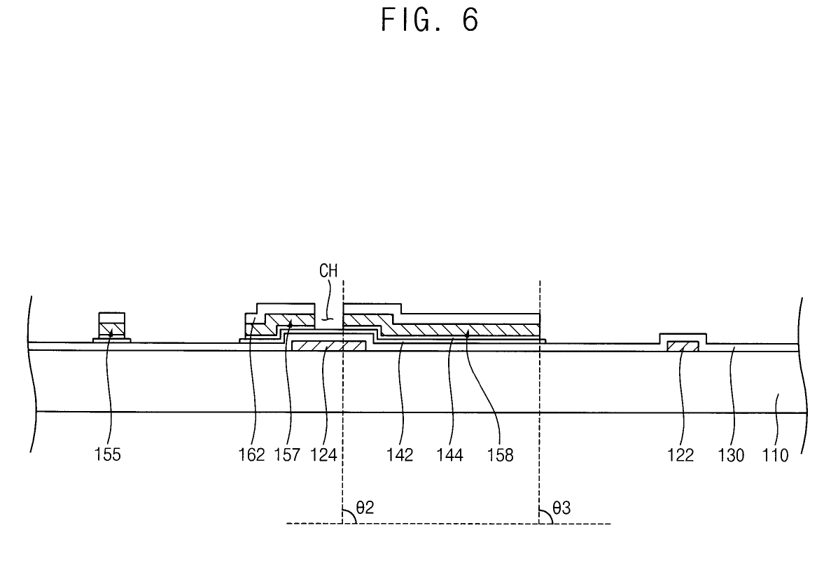

Referring to FIG. 6, the second portion of the first photoresist pattern 160 is removed, and the first portion remains, albeit with a reduced thickness. Hereinafter, after the second portion is removed, the first photoresist pattern 160 including a remaining first portion will be referred as “a remaining photoresist pattern” 162.

The remaining photoresist pattern 162 exposes the switching pattern 156 formed under the first portion. In one exemplary embodiment, the remaining photoresist pattern 162 may be formed through ashing the first photoresist pattern 160 by plasma.

The switching pattern 156 is etched by using the remaining photoresist pattern 162 as an etching mask to form a source electrode 157 connected to the data line 155 and a drain electrode 158 spaced apart from the source electrode 157. The source electrode 157 is connected to the data line 155 to serve as a source terminal of the TFT. The drain electrode 158 is spaced apart from the source electrode 157 to serve as a drain terminal of the TFT. In one exemplary embodiment, the switching pattern 156 may be etched through a dry etching process. Alternative exemplary embodiments include configurations wherein the switching pattern 156 may be etched through a wet etching process.

Thereafter, an exposed portion of the ohmic contact layer 144 is etched using the source electrode 157, the drain electrode 158 and the remaining photoresist pattern 162 as an etching mask to remove the exposed portion so as to form a channel portion CH. Thereafter, the remaining photoresist pattern 162 remaining on the base substrate 110 may be removed through a stripping process using a stripping solution.

According to an exemplary embodiment of the present invention, angles θ2 and θ3 formed between a sidewall of the remaining photoresist pattern 162 and an upper surface of the base substrate 110 may be increased. Thus, an etched side surface of the ohmic contact layer 144 may substantially coincide with etched side surfaces of the source electrode 157 and the drain electrode 158, which are adjacent to the channel portion CH. Therefore, a protrusion of the ohmic contact layer 144, which laterally protrudes from the source electrode 157 and the drain electrode 158, may be reduced or effectively prevented. Thus, an aperture ratio of the channel portion CH may be increased, and electrical characteristics of the TFT maybe improved.

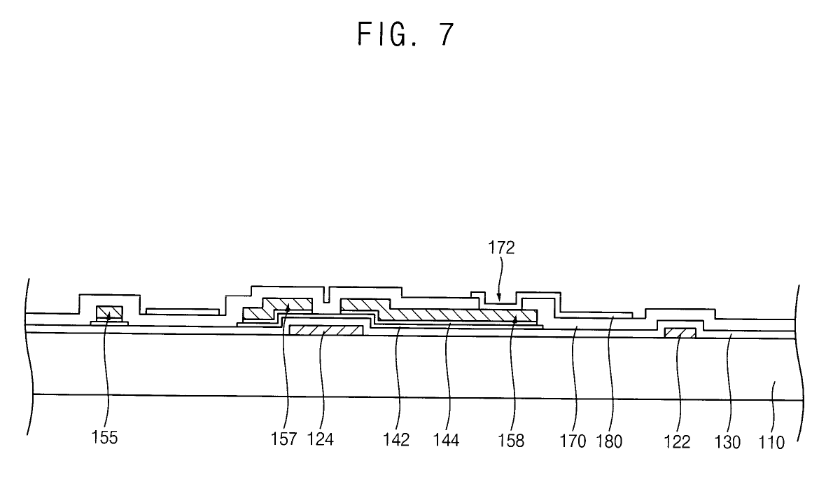

Referring to FIG. 7, a passivation layer 170 is formed on the base substrate 110 having the TFT. The passivation layer 170 protects and insulates the TFT and the data line 155. In one exemplary embodiment, the passivation layer 170 may include silicon nitride, silicon oxide, and other materials having similar characteristics. In one exemplary embodiment, the passivation layer 170 may be formed through a chemical vapor deposition (“CVD”) method, and a thickness of the passivation layer 170 may be about 500 Å to about 2,000 Å. In one exemplary embodiment, the passivation layer 170 may be patterned through a photolithography process using a third mask to form a contact hole 172 exposing a portion of the drain electrode 158.

A transparent conductive layer is formed on the passivation layer 170. The transparent conductive layer is patterned through a photolithography process using a fourth mask to form a pixel electrode 180. In one exemplary embodiment the pixel electrode 180 may include indium zinc oxide, indium tin oxide, and other materials having similar characteristics. The pixel electrode 180 may be in a region surrounded by adjacent gate lines 122 and adjacent data lines 155. In one exemplary embodiment, the pixel electrode 180 may be electrically connected to the drain electrode 158 through the contact hole 172 formed through the passivation layer 170.

In an alternative exemplary embodiment an organic insulation layer (not shown) may be formed on the passivation layer 170 before the pixel electrode 180 is formed in order to planarize the base substrate 110.

According to the above described exemplary embodiments, a photoresist composition according to an exemplary embodiment of the present invention may improve a sensitivity, a developing contrast between an exposed portion and an unexposed portion, and the residual uniformity of a half-exposed portion. Furthermore, the photoresist composition may increase adhesion to a substrate thereby increasing reliability of a metal pattern. Therefore, the reliability and efficiency of manufacturing processes may be increased.

Although exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A photoresist composition comprising:
a novolac resin prepared from a phenol compound, wherein m-cresol constitutes about 70% to about 85% of the weight of the phenol compound;
a diazide compound; and
an organic solvent.

2. The photoresist composition of claim 1, wherein the novolac resin comprises:
a first novolac resin prepared from a phenol compound, wherein the phenol compound includes m-cresol and p-cresol in a ratio of about 40:60 to about 60:40 by weight; and
a second novolac resin prepared from a phenol compound, wherein the phenol compound includes m-cresol and p-cresol in a ratio of about 90:10 to about 100:0 by weight.

3. The photoresist composition of claim 2, wherein the novolac resin includes the first novolac resin and the second novolac resin in a ratio of about 60:40 to about 40:60 by weight.

4. The photoresist composition of claim 1, wherein the novolac resin comprises:
a first novolac resin prepared from a phenol compound, wherein the phenol compound includes m-cresol and p-cresol in a ratio of about 50:50 to about 60:40 by weight; and
a second novolac resin prepared from a phenol compound, wherein the phenol compound includes m-cresol and p-cresol in a ratio of about 80:20 to about 100:0 by weight.

5. The photoresist composition of claim 4, wherein the novolac resin includes the first novolac resin and the second novolac resin in a ratio of about 60:40 to about 40:60 by weight.

6. The photoresist composition of claim 1, wherein the weight average molecular weight of the novolac resin is about 4,000 to about 15,000 g/mol.

7. The photoresist composition of claim 1, wherein the diazide compound comprises a diazide compound combined with a phenol compound.

8. The photoresist composition of claim 7, wherein the weight average molecular weight of the phenol compound combined with the diazide compound is about 500 to about 1,500 g/mol.

9. The photoresist composition of claim 1, wherein the diazide compound comprises:
1,2-naphthoquinonediazide-5-sulfonate combined with a phenol compound; and
2,3,4-trihydroxybenzophenone-1,2-naphthoquinonediazide-5-sulfonate.

10. The photoresist composition of claim 9, wherein the weight ratio of the 1,2-napthoquinonediazide-5-sulfonate combined with the phenol compound and the 2,3,4-trihydroxybenzophenone-1,2-naphthoquinonediazide-5-sulfonate is about 40:60 to about 60:40.

11. The photoresist composition of claim 1, wherein the photoresist composition comprises:
about 5% to about 30% by weight of the novolac resin;
about 2% to about 10% by weight of the diazide compound; and
a remainder of the weight of the composition is the organic solvent.

12. A method of manufacturing an array substrate, the method comprising:
disposing a source metal layer on a base substrate having a gate line and a gate electrode connected to the gate line;
disposing a photoresist pattern on the source metal layer, the photoresist pattern being formed from a photoresist composition comprising:
a novolac resin prepared from a phenol compound, wherein m-cresol constitutes about 70% to about 85% of the weight of the phenol compound;
a diazide compound; and
an organic solvent;
forming a data line crossing the gate line, a source electrode connected to the data line and a drain electrode spaced apart from the source electrode using the photoresist pattern; and
electrically connecting a pixel electrode to the drain electrode.

13. The method of claim 12, wherein forming the drain electrode comprises:
etching the source metal layer using the photoresist pattern as an etching mask, the photoresist pattern comprising:
a first portion having a first thickness and overlapping the data line, the source electrode and the drain electrode; and
a second portion having a second thickness smaller than the first thickness and overlapping with a gap between the source and drain electrodes;
removing the second portion to expose a portion of the source metal layer corresponding to a gap between the source and drain electrodes while leaving a remnant of the first portion; and
etching an exposed portion of the source metal layer using the first portion to form the source and drain electrodes.

14. The method of claim 13, further comprising:
disposing an active layer between the gate electrode and the source metal layer and between the gate line and the source metal layer;
etching the active layer using the photoresist pattern comprising the first and second portions as an etching mask; and
forming a channel portion using the remnant of the first portion as an etching mask.

15. The method of claim 12, wherein the novolac resin comprises:
a first novolac resin prepared from a phenol compound, wherein the phenol compound includes m-cresol and p-cresol in a ratio of about 40:60 to about 60:40 by weight; and
a second novolac resin prepared from a phenol compound, wherein the phenol compound includes m-cresol and p-cresol in a ratio of about 90:10 to about 100:0 by weight.

16. The method of claim 12, wherein the diazide compound comprises:
1,2-naphthoquinonediazide-5-sulfonate combined with a phenol compound; and
2,3,4-trihydroxybenzophenone-1,2-naphthoquinonediazide-5-sulfonate.
